(19) United States
(12) Patent Application Publication
(10) Pub. No.: US 2007/0114592 A1
(43) Pub. Date: May 24, 2007

(54) Method of forming non-volatile memory cell using spacers and non-volatile memory cell formed according to the method

(75) Inventors: Steven R. Soss, San Jose, CA (US); Krishna Parat, Palo Alto, CA (US)

Correspondence Address: INTEL CORPORATION;c/o INTELLEVATE, LLC, P.O. BOX 52050, MINNEAPOLIS, MN, 55402, US

(73) Assignee: Intel Corporation

(21) Appl. No.: 11/284,485

(22) Filed: Nov. 21, 2005

(51) Int. Cl. H01L 29/788; H01L 21/336

(52) U.S. Cl. 257/316; 438/264; 438/257; 257/321

(57) ABSTRACT

A method of forming a microelectronic non-volatile memory cell, a non-volatile memory cell made according to the method, and a system comprising the non-volatile memory cell. The method comprises: providing a substrate; providing a pair of spaced apart isolation regions in the substrate, providing the pair comprising providing a buffer layer on the substrate; removing the buffer layer; providing a tunnel dielectric on a surface of the substrate after removing the buffer layer; providing a pair of device spacers on side walls of each of the isolation regions extending above the surface of the substrate; providing a floating gate on the tunnel dielectric; providing a source region and a drain region on opposite sides of the floating gate; providing an interpoly dielectric on the floating gate; and providing a control gate on the interpoly dielectric to yield the memory cell.

### FIELD

Embodiments relate to the field of microelectronic manufacturing, and, more specifically, to a method of fabricating a non-volatile memory or flash cell and to a flash cell formed according to the method.

### BACKGROUND

The scaling of flash cells presents a number of challenges, one of which is to control the amount of floating gate endcap, that is, the amount by which the floating gate of a flash cell overhangs the active substrate of the cells into the isolation regions.

A conventional electrically erasable nonvolatile flash cell 100 is shown in FIG. 1 stacked with other similar cells at each side thereof, only half of each of the similar cells having been shown on each side of cell 100. Flash cell 100 includes polysilicon floating gate 102 formed on tunnel dielectric 104, which is in turn formed on the silicon region 106. An interpoly dielectric 108 is formed on the polysilicon floating gate, a control gate 110 is formed on the interpoly dielectric layer 108, and a pair of source/drain regions (not shown) is formed along opposite sides of floating gate electrode 102. To store information in flash cell 100, charge is stored on floating gate 102. To erase flash cell 100, charge is removed from floating gate 102. A problem with flash cell 100 shown in FIG. 1, is that it has become difficult to further scale down its width and length to form smaller area cells and higher density memory circuits. In particular, scaling of the flash cell typically requires that a half pitch of the process node equal two times the floating gate endcap (FGEC), plus two times the interpoly dielectric thickness (IPD), plus the control gate width (CGW), as shown in FIG. 1. Conventionally, FGEC is typically about 10 nm, making the scaling of a 45 nm flash cell extremely challenging, and that of a 32 nm flash cell or lower almost impossible.

Current methods of solving the above problem involve either de-scaling the flash cell, that is, making the cell size larger than the half pitch of the process node described above, and/or by trading the line/space ratio to descale the isolation width. In the latter case, the width of isolation regions, such as regions 115 of memory device 100, is designed to be larger to allow for material from the isolation region to be laterally etched during the removal of the original buffer layer used as part of a formation of the isolation regions. In other words, the prior art makes the lines smaller, and the spaces much bigger. However, an optimum device performance would occur when the lines are at least equal in width to the spaces, if not wider. Thus, both of the above methods are undesirable to the extent that they trade flash cell performance for process limitations.

The prior art fails to provide a method of forming a flash cell that allows a reliable scaling of the flash cell into the 45 nm range and below.

### BRIEF DESCRIPTION OF THE DRAWINGS

Embodiments of the invention are illustrated by way of example and not by way of limitation in the figures of the accompanying drawings, in which the like references indicate similar elements and in which:

FIG. 1 is a cross-sectional view of a flash cell according to the prior art;

FIGS. 2a and 2b are cross-sectional views similar to FIG. 1 showing respective embodiments of a flash cell;

FIGS. 3a-3d show stages of a method embodiment to form the flash cell of FIG. 2a/2b;

FIGS. 4a-4d show stages of a first embodiment to form the flash cell of FIG. 2a;

FIGS. 5a-5d show stages of a second embodiment to form the flash cell of FIG. 2b; and

FIG. 6 is a schematic view of a system incorporating a flash cell according to an embodiment.

### DETAILED DESCRIPTION

A method of forming a flash cell using spacers, a flash cell according to the method, and a system including the flash cell are disclosed herein.

Various aspects of the illustrative embodiments will be described using terms commonly employed by those skilled in the art to convey the substance of their work to others skilled in the art. However, it will be apparent to those skilled in the art that the present invention may be practiced with only some of the described aspects. For purposes of explanation, specific numbers, materials and configurations are set forth in order to provide a thorough understanding of the illustrative embodiments. However, it will be apparent to one skilled in the art that the present invention may be practiced without the specific details. In other instances, well-known features are omitted or simplified in order not to obscure the illustrative embodiments.

Various operations will be described as multiple discrete operations, in turn, in a manner that is most helpful in understanding the present invention, however, the order of description should not be construed as to imply that these operations are necessarily order dependent. In particular, these operations need not be performed in the order of presentation.

The phrase “in one embodiment” is used repeatedly. The phrase generally does not refer to the same embodiment, however, it may. The terms “comprising”, “having” and “including” are synonymous, unless the context dictates otherwise.

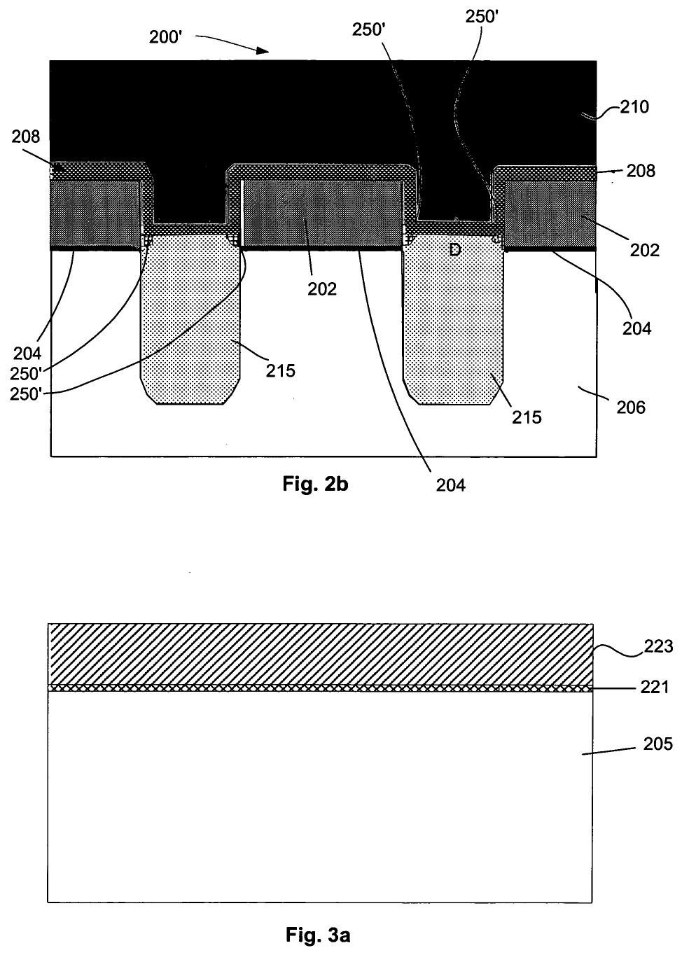

Referring first to FIGS. 2a and 2b, flash memory cells fabricated according to two respective method embodiments are depicted. The flash cell shown in FIG. 2a and the flash cell shown in FIG. 2b are almost identical except (1) for the respective sizes of the device spacers 250 and 250′ as will be described further below with respect to the two method embodiments, and (2) for the fact that, while the flash cell of FIG. 2a exhibits some endcap extension, the flash cell of FIG. 2b exhibits zero endcap extension. To the extent that the flash cell in FIG. 2a and the flash cell in FIG. 2b are almost identical, various components in the respective flash cells are labeled with identical reference numerals. Where FIGS. 2a and 2b or flash cells 200 and 200′, and device spacers 250 and 250′ are being referred to in the alternative, the respective notations “FIG. 2a/2b,” flash cells 200/200′,” and “device spacers 250/250′” are used herein.

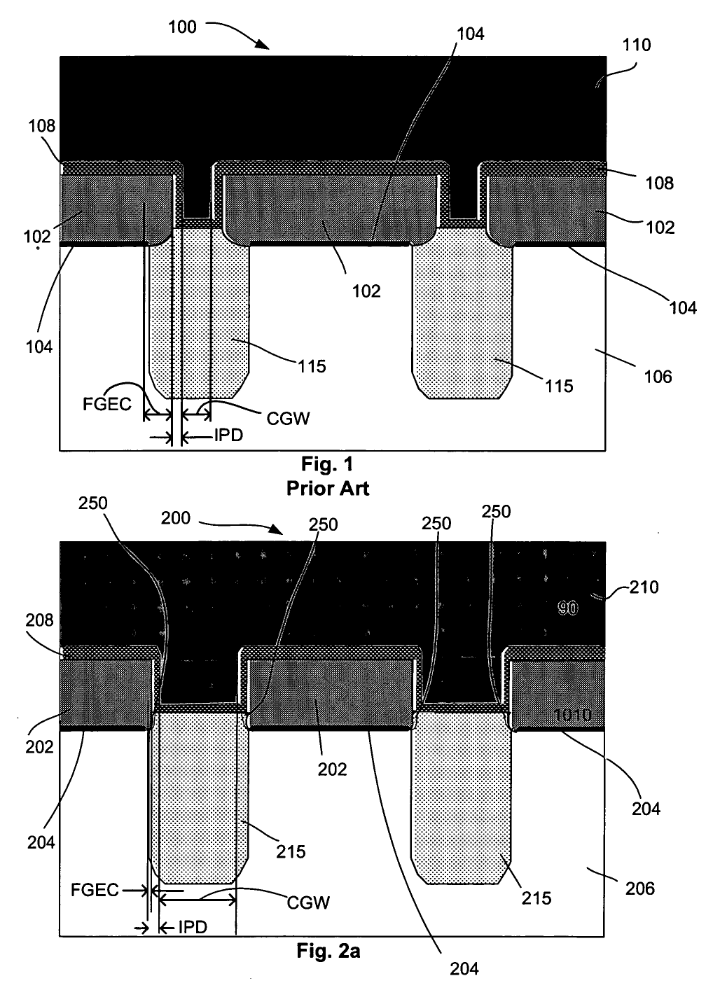

Referring then to FIG. 2a/2b, flash cell 200/200′ is, similar to cell 100 of FIG. 1, shown as having been stacked along with other similar cells, only half of the similar cells having been shown on each side of cell 200/200′. Flash cell 200/200′ includes a floating gate 202 formed on the tunnel dielectric 204 which is formed on the substrate region 206. Tunnel dielectric 204 is further provided. An interpoly dielectric 208 is formed on the floating gate and a control gate 210 formed on the interpoly dielectric layer 208 and a pair of source/drain regions (not shown) is formed along opposite sides of floating gate 202. A pair of isolation regions 215 flanks the floating gate 204, the isolation regions comprising, for example, a silicon oxide or a silicon dioxide material. Cell 200 further comprises oxide device spacers 250/250′ between each of side walls of the floating gate and adjacent side walls of the corresponding raised isolation regions. The device spacers may comprise silicon dioxide, and thus, may, according to an embodiment, comprise a material identical to a material of the isolation regions.

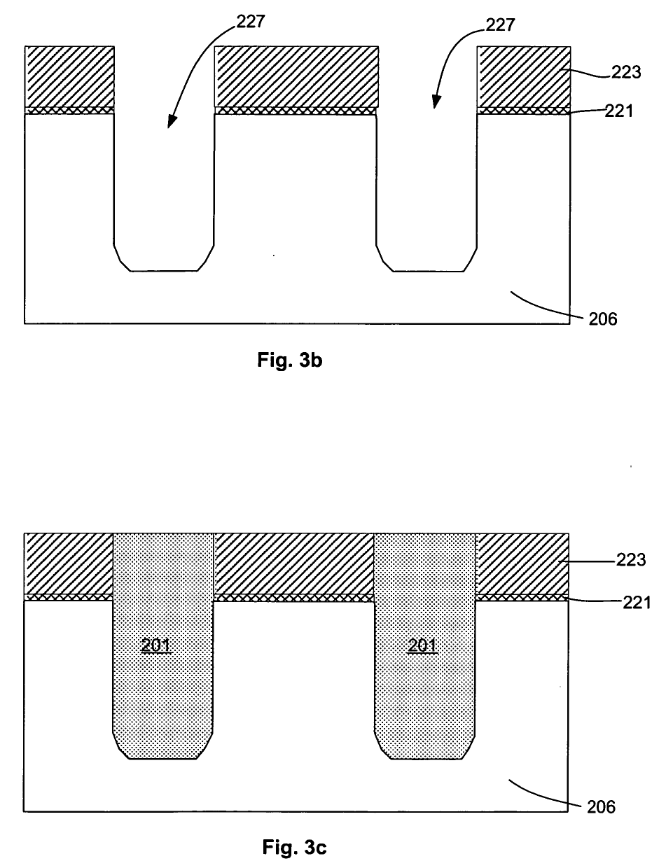

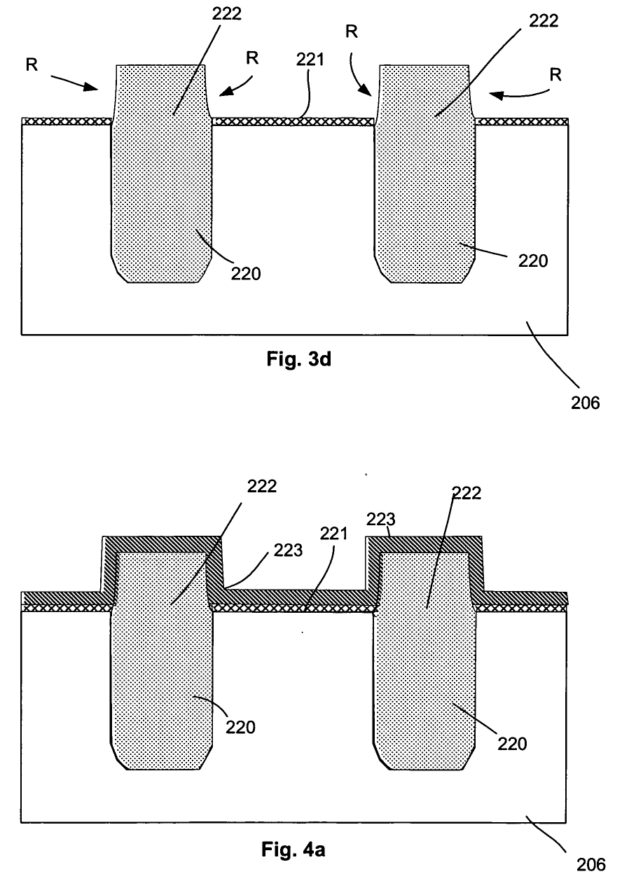

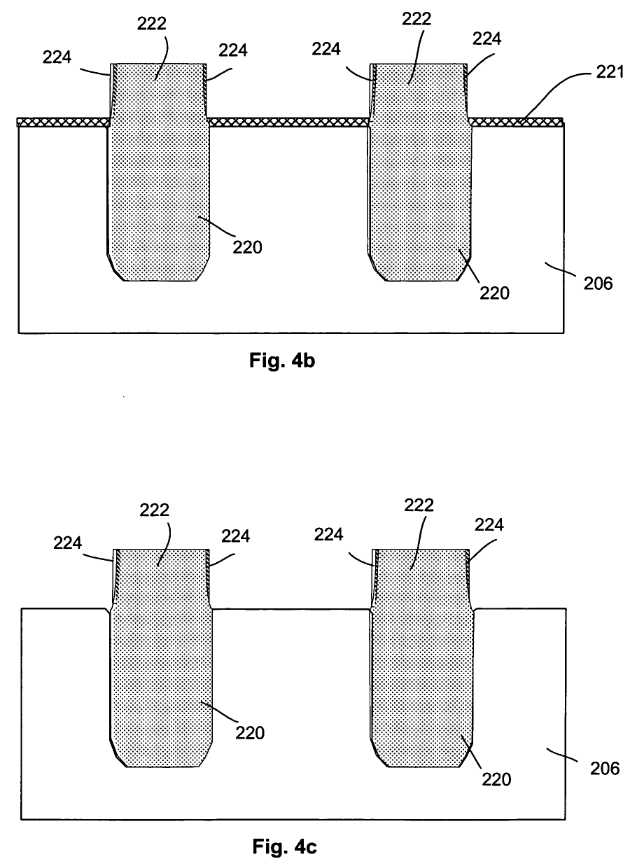

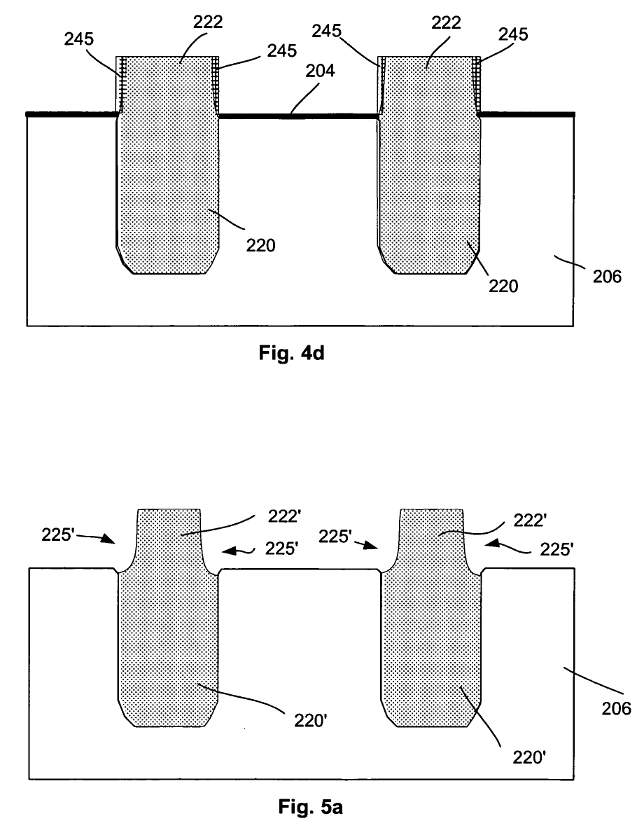

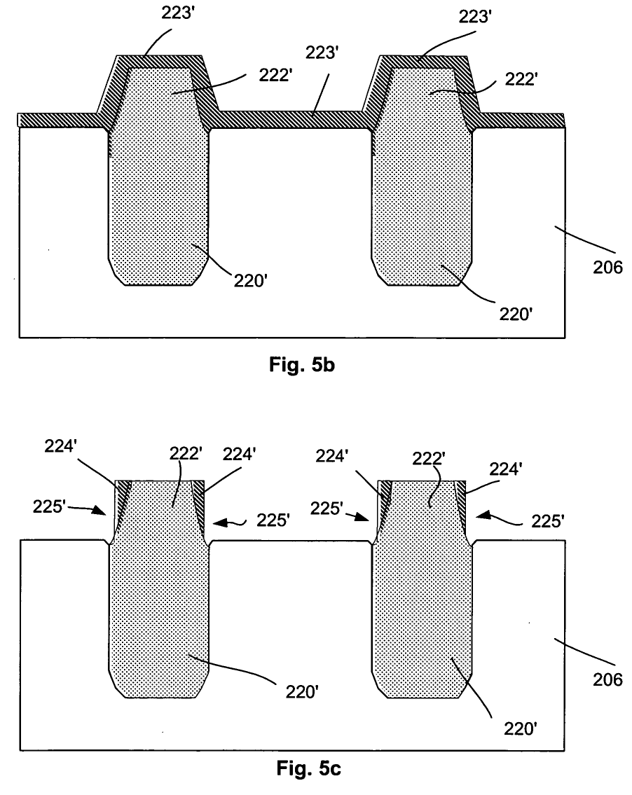

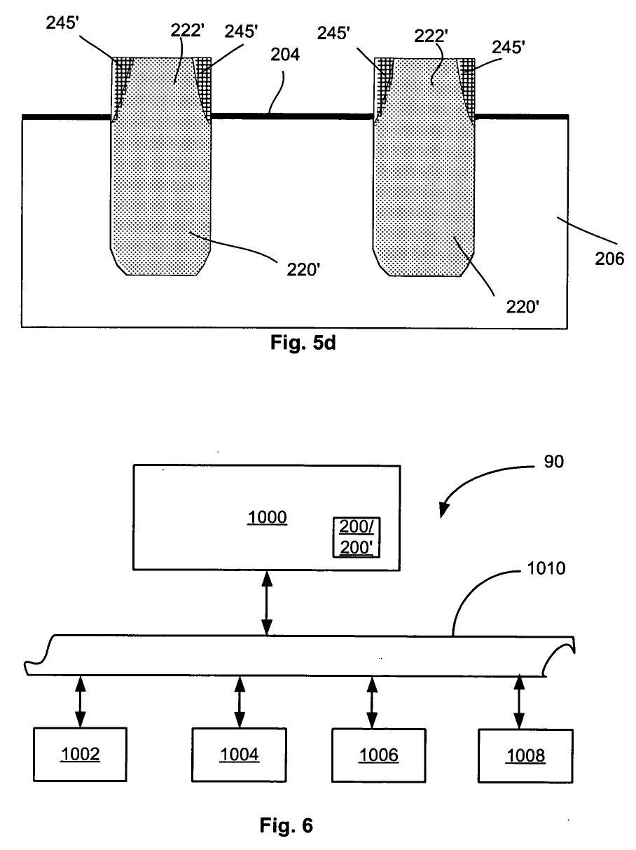

A method of forming a flash cell in accordance with embodiments of the present invention will now be explained with respect to cross-sectional illustrations shown in FIGS. 3a-3d, 4a-4d and 5a-5d. FIGS. 4a-4d depict a method according to a first embodiment to form flash cell 200 of FIG. 2a, FIGS. 5a-5d depict a method according to a second embodiment to form flash cell 200′ of FIG. 2b, while FIGS. 3a-3d depict initial stages of formation of a flash cell according to embodiments, which stages pertain to both the first embodiment shown in FIGS. 4a-4d and to the second embodiment shown in FIGS. 5a-5d.

As shown in FIG. 3a by way of example, a first stage of forming a flash cell according to embodiments comprises providing a substrate including a buffer layer thereon, and a polish stop layer on the buffer layer. The substrate may, in one embodiment, include a silicon substrate 206 as shown. In an embodiment of the present invention, the substrate includes a monocrystalline silicon substrate 206. The starting substrate need not, however, be a silicon epitaxial film formed on a monocrystalline silicon substrate and can include other types of substrates. The polish stop layer may, in one embodiment comprise a nitride layer 223 as shown. The buffer layer may, in one embodiment, comprise a buffer layer 221, such as, for example, a layer made of a thermal oxide, a deposited oxide or an oxynitride. The buffer layer may be provided as a stress relief layer between the polish stop layer and the substrate. The buffer layer and the polish stop layer may be provided onto the substrate in any of the manners known to one skilled in the art.

Referring next to FIG. 3b by way of example, a second stage of forming a flash cell according to embodiments comprises providing a pair of isolation recesses into the initial substrate and through the polish layer and the buffer layer. Thus, as seen in FIG. 3b, the pair of isolation recesses 227 may be provided into the substrate 206 as shown, through the buffer layer 221 and through the polish stop layer 223. The provision of the pair of isolation recesses may be effected through well know techniques, such as, for example, photolithography, as would be recognized by one skilled in the art. Providing the isolation recesses may further include growing a liner oxide on the side walls of the recesses to passivate the side walls (not shown).

Referring next to FIG. 3c by way of example, a next stage of forming a flash cell according to embodiments comprises filling the pair of isolation recesses with a trench fill material to provide a pair of corresponding isolation blocks. Thus, as seen in FIG. 3c, the pair of isolation recesses 227 is shown as having been filled with a trench fill material to provide the corresponding pair of isolation blocks 201. The trench fill material may, for example, comprise silicon oxide blanket deposited by chemical vapor deposition (CVD), or silicon dioxide formed either by a sequential deposition/etch/deposition process or by a simultaneous deposition-etch process, such as a high density plasma deposition process. Excess trench fill material on a top region of the isolation blocks may then be polished back such as by chemical mechanical polishing (CMP), as would be recognized by one skilled in the art, the polish stop layer 223 acting as a polish stop in order to delimit a top surface of each of the isolation blocks 201.

Referring next to FIG. 3d by way of example, a next stage of forming a flash cell according to embodiments comprises removing the polish stop layer to provide a pair of isolation bodies. For example, as shown in FIG. 3d, the polish stop layer may be removed in a well known manner to yield isolation bodies 220 including raised isolation portions 222, that is, portions extending above a top surface of the silicon substrate 206. It is noted that a process flow up to a removal of the polish stop layer such as layer 223 may in some instances, as would be recognized by one skilled in the art, result in some etching away of side regions of the raised isolation portions 222, as noted by recesses R in FIG. 3d, to result in the isolation bodies. Thus recesses R may for example be caused by clean procedures after ion implantation subsequent to a removal of the polish stop layer.

As previously noted, FIGS. 4a-4d will now be described with reference to stages in forming a flash cell according to a first method embodiment, such as flash cell 200 of FIG. 2a. FIGS. 5a-5d will then be described with reference to stages in forming a flash cell according to a second embodiment, such as flash cell 200′ of FIG. 2b.

Referring next to FIG. 4a-4b by way of example, a next stage of forming a flash cell according to embodiments comprises providing pillar spacers on side walls of the raised isolation portions of FIG. 3d. The pillars may for example be in the form of pillar spacers 224 as shown in FIG. 4b. In one embodiment, the provision of pillar spacers may include an initial provision of a conformal spacer layer on the buffer layer and on the raised isolation portions, and, thereafter, an anisotropic etching of the layer in a direction toward the substrate in order to yield the pillar spacers. For example, as shown in FIG. 4a, a conformal spacer layer 223 may first be provided onto the buffer layer and onto the isolation bodies. The spacer layer may, for example, include a deposited silicon such as polycrystalline silicon, silicon nitride or amorphous silicon, and may be provided using hot-wall CVD, cold-wall CVD, or PECVD. Thereafter, as shown in FIG. 4b, the conformal spacer layer 223 may be anisotropically etched, such as, for example, using a dry etch, to form pillar spacers 224 on side walls of the raised isolation portions 222. Types of dry etches that may be used to effect an anisotropic etching of the conformal spacer layer according to embodiments would be within the knowledge of one skilled in the art. A thickness of the spacer layer may be determined by a number of factors, which include the amount of lateral etch of the isolation bodies before deposition of the spacer layers and the expansion rate of the silicon after oxidation, which expansion rate typically corresponds to a twofold expansion in size with respect to an original thickness of the pillar spacer. The thickness of the spacer layer may thus be tuned to ensure that a lateral width of the resulting isolation regions (such as isolation regions 215 of FIG. 2a) is at a desired, predetermined value. Pillar spacers such as pillar spacers 224 shown in FIG. 4b may thus extend along sidewalls of raised isolation portions 222 as shown, and down onto the buffer layer 221.

Referring next to FIG. 4c by way of example, a next stage of forming a flash cell according to an embodiment comprises removing the buffer layer, for example using etching. Thus, as seen by way of example in FIG. 4c, the buffer layer 221 is shown as having been removed via etching, having left behind the pillar spacers 224 and isolation bodies 220 as shown. Where etching, such as an isotropic wet etch, is used to remove the buffer layer 221, removal of the same advantageously prevents a further recessing of the isolation bodies that would have occurred in the prior art had the pillar spacers not been present. To remove the buffer layer, any suitable wet etch may be used, such as, for example, a wet etch using HF.

Referring next to FIG. 4d by way of example, a stage in the formation of a flash cell such as the flash cell 200 of FIG. 2a comprises oxidizing the pillar spacers during a provision of the tunnel dielectric to yield oxidized spacers. Thus, starting for example from the structure of FIG. 4c, a next stage in the formation of the flash cell may comprise providing a tunnel dielectric 204 comprising a tunnel oxide by growing the tunnel oxide onto the surface of the substrate disposed between the pillar spacers 224, while simultaneously growing an oxide from a material of the pillar spacers to form oxidized spacers 245. The oxidized spacers 245 may thus comprise a thermal oxide material. Typically, an oxidation of pillar spacers 224 results in a substantially twofold increase in size of the same when the pillar spacers change into oxidized spacers 245.

Subsequent to a provision of the tunnel oxide and an oxidization of the pillar spacers as explained by way of example with respect to FIG. 4d, formation of a flash cell according to embodiments may continue, as would be recognized by one skilled in the art, according to any standard process flow, including providing (as seen for example in FIG. 2a): a floating gate (such as floating gate 202), an interpoly dielectric (such as interpoly dielectric 208), a control gate (such as control gate 210), and source/drain implants, in order to yield a flash cell, such as flash cell 200 of FIG. 2a. Provision of the floating gate, as is well known, may be effected by depositing a layer of polysilicon and patterning the layer to be self-aligned to the active region (that is, to be self-aligned to the active surface of the substrate). Patterning of the layer of polysilicon corresponding to the floating gate could be effected by either polishing or etching the layer according to conventional techniques. The isolation bodies are reduced in height, such as through etching, to the levels of the isolation regions, such as isolation regions 215 of FIG. 2a after the provision of the floating gates, as would be recognized by one skilled in the art. In addition, the oxidized spacers 245 are reduced in height to yield the device spacers 250 of FIG. 2a. A reduction in height of oxidized spacers 245 may occur through etching, and may further be effected simultaneously with a reduction in height of the isolation bodies as noted above. As previously noted with respect to FIG. 2a, the device spacers 250 may comprise the same oxide as the oxide of the isolation bodies. Thus, the line of demarcation between device spacers 250 and the isolation regions 25 in FIGS. 2a and 2b, where the device spacers 250 are in fact made of the same material as that of the isolation regions, would merely correspond to a line indicating where a material of the isolation regions would correspond to the material of the device spacers 250. In addition, while flash cell 200 of FIG. 2a exhibits a positive amount of FGEC extension as shown, embodiments comprise within their scope the provision of device spacers according to the first method embodiment as described by way of example with respect to FIGS. 4a-4d where the FGEC is substantially zero. Where the FGEC extension has a positive value in a flash cell made according to the first embodiment, the FGEC may have a value up to about 60 nm, and preferably up to about 40 nm.

FIGS. 5a-5d will now be described with reference to stages in forming a flash cell according to a second embodiment as shown by way of example in FIG. 2b.

Referring first to FIG. 5a by way of example, a next stage of forming a flash cell according to an embodiment comprises removing the buffer layer, for example using etching. Thus, as seen by way of example in FIG. 5a, the buffer layer 221 is shown as having been removed via etching, having left behind the isolation bodies 220′ as shown, the isolation bodies 220′ including raised isolation portions 222′ defining deep recesses 225′, the recesses 225′ extending well into the trench isolation material of the isolation bodies 220′. The recessing may, for example, be above about 60 nm. Such recessing, without the use of pillar spacers as will be described in relation to the second embodiment of FIGS. 5a-5d, may in turn bring about the significant floating gate end cap extension as shown for example in FIG. 1, which can make the scaling of flash cells below the 45 nm node difficult. To remove the buffer layer, any suitable wet etch may be used, such as, for example, a wet etch using HF.

Referring next to FIG. 5b-5c by way of example, a next stage of forming a flash cell according to embodiments comprises providing pillar spacers on side walls of the modified raised isolation portions 222′ of FIG. 5a. The pillars may for example be in the form of pillar spacers 224′ as shown in FIG. 5c. In one embodiment, the provision of pillar spacers may include an initial provision of a conformal spacer layer on the raised isolation portions, and, thereafter, an anisotropic etching of the layer in a direction toward the substrate in order to yield the pillar spacers. For example, as shown in FIG. 5b, a conformal spacer layer 223′ may first be provided onto the buffer layer and onto the isolation bodies. The spacer layer may, for example, include a deposited silicon such as polycrystalline silicon or amorphous silicon, and may be provided using hot-wall CVD, cold-wall CVD, or PECVD. Thereafter, as shown in FIG. 5d, the conformal spacer layer 223′ may be anisotropically etched, such as, for example, using a dry etch, to form pillar spacers on side walls of the raised isolation portions 222′. Types of dry etches that may be used to effect an anisotropic etching of the conformal spacer layer according to embodiments would be within the knowledge of one skilled in the art. A thickness of the spacer layer, as noted above, is determined by a number of factors, which include the amount of lateral etch of the isolation bodies before deposition of the spacer layers and the expansion rate of the silicon after oxidation, which expansion rate typically corresponds to a twofold expansion in size with respect to an original thickness of the pillar spacer. The thickness of the spacer layer may thus be tuned to ensure that a lateral width of the isolation regions (such as isolation regions 215 of FIG. 2b) is at a desired, predetermined value. Pillar spacers such as spacers 224′ shown in FIG. 5c may thus extend along sidewalls of raised isolation portions 222′ as shown.

Referring next to FIG. 5d by way of example, a next stage in the formation of a flash cell such as the flash cell 200 of FIG. 2bcomprises oxidizing the pillar spacers during a provision of the tunnel dielectric to yield oxidized spacers 245′. Thus, starting for example from the structure of FIG. 5c, a next stage in the formation of the flash cell may comprise providing a tunnel dielectric 204 comprising a tunnel oxide by growing the tunnel oxide onto the surface of the substrate disposed between the pillar spacers 224′, while simultaneously growing an oxide from a material of the pillar spacers to form oxidized spacers 245′. The oxidized spacers 245′ may thus comprise a thermal oxide material.

Subsequent to a provision of the tunnel oxide and an oxidization of the pillar spacers as explained by way of example with respect to FIG. 5d, formation of a flash cell according to embodiments may continue, as would be recognized by one skilled in the art, according to any standard process flow, including providing (as seen for example in FIG. 2b): a floating gate (such as floating gate 202), an interpoly dielectric (such as interpoly dielectric 208), a control gate (such as control gate 210), and source/drain implants, in order to yield a flash cell, such as flash cell 200 of FIG. 2b. The isolation bodies are reduced in height, such as through etching, to the levels of the isolation regions 215 of FIG. 2b after the provision of the floating gates, as would be recognized by one skilled in the art. In addition, the oxidized spacers 245′ are reduced in height to yield the device spacers 250′ of FIG. 2b. A reduction in height of oxidized spacers 245′ may occur through etching, and may further be effected simultaneously with a reduction in height of the isolation bodies as noted above. As previously noted with respect to FIG. 2b, the device spacers 250′ may comprise the same oxide as the oxide of the isolation regions. In addition while flash cell 200′ of FIG. 2b exhibits an FGEC extension that is substantially equal to zero as shown, embodiments comprise within their scope the provision of device spacers according to the first method embodiment as described by way of example with respect to FIGS. 5a-5d where the FGEC may have a positive value, such as, for example, a value up to about 60 nm, and preferably up to about 40 nm.

Comparing now the flash cell of FIG. 2a with the flash cell of FIG. 2b, device spacers 250 of the flash cell of FIG. 2a are smaller than device spacers 250′ of the flash cell of FIG. 2b, all else being equal, to the extent that the device spacers 250 were formed in smaller recesses R within the isolation bodies 220 (FIG. 3d) than device spacers 250′, which were formed in deeper recesses 225′ within the isolation bodies 220′ (FIG. 5a).

Embodiments further comprise within their scope a method embodiment where the buffer layer such as buffer layer 221 of FIG. 3d is only partially removed before a provision of the pillar spacers, after which pillar spacers such as pillar spacers 224 of FIG. 4b are provided, and after which the rest of the buffer layer is removed. Such a method embodiment is a hybrid form of the first and second method embodiment described above and depicted in the figures. In addition, embodiments comprise within their scope the provision of device spacers that are made of a material different from a material of the isolation regions.

Advantageously, embodiments of the present invention provide a method for a precise tailoring of the floating gate endcap extension of a flash cell through the use of a pillar spacer arrangement during a fabrication of the cell. The conventional wet etch used as part of a preparation regimen for the surface onto which the tunnel dielectric is to be deposited tends to disadvantageously etch away parts of the isolation oxide which make room for the subsequent extension of the floating gate endcap. According to method embodiments, a surface to receive the tunnel dielectric may advantageously be prepared independently of the endcap's extension. In addition, advantageously, embodiments allow the scaling of flash cells without compromising the space between adjacent floating gates necessary to support the IPD and the control gate wrap-around. Moreover, embodiments allow both a positive and a negative tuning of the endcap extension. Thus, a positive tuning would correspond to a tuning of the endcap extension into the isolation regions, and a negative tuning would correspond to a tuning of the endcap extension in a direction away from the isolation regions. In addition, advantageously, the use of silicon spacers that convert to oxide spacers as described above allows a tuning of the amount of isolation material desired to be put back in regions of the isolation bodies that may have been recessed during processing.

Referring to FIG. 6, there is illustrated one of many possible systems 900 in which embodiments of the present invention may be used. The electronic assembly 1000 may include a flash cell similar to the flash cell 200/200′ depicted in FIG. 2a/2b. In one embodiment, the electronic assembly 1000 may include a microprocessor. In an alternate embodiment, the electronic assembly 1000 may include an application specific IC (ASIC). Integrated circuits found in chipsets (e.g., graphics, sound, and control chipsets) may also be packaged in accordance with embodiments of this invention.

For the embodiment depicted by FIG. 6, the system 90 may also include a main memory 1002, a graphics processor 1004, a mass storage device 1006, and/or an input/output module 1008 coupled to each other by way of a bus 1010, as shown. Examples of the memory 1002 include but are not limited to static random access memory (SRAM) and dynamic random access memory (DRAM). Examples of the mass storage device 1006 include but are not limited to a hard disk drive, a compact disk drive (CD), a digital versatile disk drive (DVD), and so forth. Examples of the input/output module 1008 include but are not limited to a keyboard, cursor control arrangements, a display, a network interface, and so forth. Examples of the bus 1010 include but are not limited to a peripheral control interface (PCI) bus, and Industry Standard Architecture (ISA) bus, and so forth. In various embodiments, the system 90 may be a wireless mobile phone, a personal digital assistant, a pocket PC, a tablet PC, a notebook PC, a desktop computer, a set-top box, a media-center PC, a DVD player, and a server.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiment shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

What is claimed is:

1. A method of forming a microelectronic non-volatile memory cell comprising:
providing a substrate;
providing a pair of spaced apart isolation regions in the substrate, providing the pair comprising providing a buffer layer on the substrate;
removing the buffer layer;
providing a tunnel dielectric on a surface of the substrate after removing the buffer layer;
providing a pair of device spacers on side walls of each of the isolation regions extending above the surface of the substrate;
providing a floating gate on the tunnel dielectric;
providing an interpoly dielectric on the floating gate; and
providing a control gate on the interpoly dielectric to yield a floating gate-control gate stack; and
providing source and drain regions on opposite sides of the floating gate-control gate stack to yield the memory cell.

2. The method of claim 1, wherein:
providing the pair of spaced apart isolation regions comprises:
providing a pair of spaced apart isolation bodies in the substrate, the isolation bodies including respective raised isolation portions, providing the pair of spaced apart isolation bodies comprising providing the buffer layer on the substrate;
reducing a height of the isolation bodies to yield the isolation regions; and
providing the pair of spacers comprises:
providing pillar spacers on side walls of the raised isolation portions;
oxidizing the pillars spacers to yield oxidized spacers; and
reducing a height of the oxidized spacers to yield the device spacers.

3. The method of claim 1, wherein removing the buffer layer comprises removing at least some of the buffer layer after providing the pillar spacers.

4. The method of claim 1, wherein removing the buffer layer comprises removing at least some of the buffer layer before providing the pillar spacers.

5. The method of claim 2, wherein providing the pillar spacers comprises:
providing a conformal spacer layer on sidewalls of the raised isolation regions; and
anisotropically etching the conformal spacer layer in a direction toward the substrate to yield the pillar spacers.

6. The method of claim 5, wherein the conformal spacer layer comprises one of an amorphous silicon, a polycrystalline silicon and silicon nitride.

7. The method of claim 5, wherein providing the conformal spacer layer comprises using one of hot-wall CVD, cold-wall CVD and PECVD.

8. The method of claim 5, wherein anisotropically etching comprises using a dry etch.

9. The method of claim 1, wherein the buffer layer comprises one of a thermal oxide, a deposited oxide and an oxynitride.

10. The method of claim 1, wherein removing the buffer layer comprises using an isotropic wet etch.

11. The method of claim 1, wherein each of the device spacers is configured such that an endcap extension of the floating gate beyond the substrate active surface of the substrate into the isolation regions is below about 60 nm.

12. The method of claim 1, wherein each of the device spacers is configured such that an endcap extension of the floating gate beyond the substrate active surface of the substrate into the isolation regions is below about 40 nm.

13. The method of claim 1, wherein the device spacers comprise silicon dioxide.

14. The method of claim 1, wherein the device spacers and the isolation regions are made of identical materials.

15. A non-volatile memory cell comprising:
a substrate;
a pair of spaced apart isolation regions provided in the substrate;
a tunnel dielectric on a substrate active surface of the substrate between the isolation regions;
a floating gate on the tunnel dielectric;
an interpoly dielectric on the floating gate and in regions between the floating gate and adjacent floating gates;
a control gate on the interpoly dielectric defining a control gate-floating gate stack;
a source region and a drain region on opposite sides of the control gate-floating gate stack;
wherein each of the pair of isolation regions comprises a device spacer disposed adjacent a corresponding side of the floating gate, each device spacer being made of a material different from a material of the isolation regions.

16. The memory cell of claim 15, wherein the floating gate has an endcap extension beyond the substrate active surface of the substrate into the isolation regions that is below about 60 nm.

17. The memory cell of claim 15, wherein the floating gate has an endcap extension beyond the substrate active surface of the substrate into the isolation regions that is below about 40 nm.

18. A system comprising:
an electronic assembly including:
a substrate;
a pair of spaced apart isolation regions provided in the substrate;
a tunnel dielectric on a substrate active surface of the substrate between the isolation regions;
a floating gate on the tunnel dielectric;
an interpoly dielectric on the floating gate and in regions between the floating gate and adjacent floating gates;
a control gate on the interpoly dielectric defining a control gate-floating gate stack;
a source region and a drain region on opposite sides of the control gate-floating gate stack;
wherein each of the pair of isolation regions comprises a device spacer disposed adjacent a corresponding side of the floating gate, each device spacer being made of a material different from a material of the isolation regions; and
a main memory coupled to the electronic assembly.

19. The memory cell of claim 17, wherein the floating gate has an endcap extension beyond the substrate active surface of the substrate into the isolation regions that is below about 60 nm.

20. The memory cell of claim 17, wherein the floating gate has an endcap extension beyond the substrate active surface of the substrate into the isolation regions that is below about 40 nm.
